(19) United States
(12) Patent Application Publication
(10) Pub. No.: US 2026/0206516 A1
(43) Pub. Date: Jul. 16, 2026

(54) WAFER CLEANING METHOD AND APPARATUS

(71) Applicant: ACM RESEARCH (SHANGHAI), INC., Shanghai (CN)

(72) Inventors: Tongtong Zhu, Shanghai (CN); Fei Zhou, Shanghai (CN); Guangming Chai, Shanghai (CN); Shu Yang, Shanghai (CN)

(73) Assignee: ACM RESEARCH (SHANGHAI), INC., Shanghai (CN)

(21) Appl. No.: 19/135,049

(22) PCT Filed: Nov. 30, 2023
(86) PCT No.: PCT/CN2023/135523

§ 371 Date: Jun. 2, 2025

(30) Foreign Application Priority Data
Dec. 2, 2022 (CN) 202211540729.9

(51) Int. Cl. H10P 70/00; A46B 13/04; C11D 3/04; C11D 3/39; H10P 72/00

(52) U.S. Cl. CPC H10P 70/20; A46B 13/04; C11D 3/04; C11D 3/042; C11D 3/044; C11D 3/3942; H10P 72/0412; H10P 72/0414; A46B 2200/3073

(57) ABSTRACT

A wafer cleaning method and apparatus clean a surface of a polished wafer. The wafer cleaning method includes: S101, wetting the surface of the wafer with DIW; S102, spraying the surface of the wafer with SC1 having a first preset temperature; S103, continuing to spray the surface of the wafer with SC1 having the first preset temperature, and controlling a brush simultaneously to scrub the surface of the wafer; S104, performing a spray cleaning on the surface of the scrubbed wafer with DIW having a second preset temperature for a first preset time; S105, repeating the steps S103 to S104 until a first preset number of times; S106, cleaning the surface of the wafer alternately with DHF and DIO₃ after executing the step S105. Through the above method, the transition step of the DIW spray cleaning at the second preset temperature can be added in multiple and continuous scrubbings.

### FIELD OF THE INVENTION

The present application relates to the field of semiconductor cleaning, in particular to a wafer cleaning method and apparatus, for cleaning the surface of the polished wafer.

### BACKGROUND

In the wafer manufacturing process, wafer single-sided polishing is one of the main polishing methods, which has the advantages of high flatness and mature technology development. The processes mainly include wax coating, loading, polishing, pre-cleaning and unloading, etc. However, after the wafer is polished, a large amount of polishing solution containing micron and nano-sized particles will remain on the front surface of the wafer, and the resin wax required for loading will remain on the back surface of the wafer, making the cleaning difficult. Therefore, cleaning the surface of the polished wafer has a key impact on product yield and is also one of the important links in wafer production.

At present, two ways are mainly used to clean the surface of the polished wafer, including multi-tanks immersion chemical wet cleaning and single wafer contact cleaning. Multi-tanks immersion chemical wet cleaning refers to placing the wafer in DIO₃ (dissolved ozone in deionized water), DHF (dilute hydrofluoric acid), SC1 (a mixture of ammonia, hydrogen peroxide and water), DIW (deionized water) and other chemical tanks for immersion in turn, so as to remove the particles, contamination and natural oxide layer on the surface of the wafer, having the advantages of mature development and high productivity. Single wafer contact cleaning firstly uses the friction process between the brush and the wafer contact in the single scrubbing chamber, combines with the action of cleaning agents such as SC1 to remove the particles on the surface of the wafer, and then enters the single cleaning chamber to peel off the surficial oxide layer through DIO₃ and DHF and removes the metal residues. Compared with multi-tanks immersion cleaning, single wafer contact cleaning can effectively improve the efficiency of single cleaning, avoid contamination between wafers, and is suitable for wafers with different thicknesses.

During the research process, it is found that the process of multi-tank immersion chemical wet cleaning is relatively simple. The process not only takes a long cleaning time and causes contamination between wafers, but also cannot effectively remove the residual wax on the back surface of the wafer after single-sided polishing. The oxide layer on the back surface of the wafer is covered by residual wax, resulting in the uneven etching. However, single wafer contact cleaning provides high requirements on the particle state, and the wafer often needs to be kept in a wet state. After the particles are dried, the particles have strong physical and chemical adsorption with the surface of the wafer. And the cleaning effect of general process is difficult to meet the production requirements.

At present, in view of the problem that the cleaning effect of the single wafer contact cleaning in the prior art is difficult to meet the production demand, no effective solution has been proposed.

### SUMMARY

An embodiment of the present application provides a method for cleaning a surface of a polished wafer, so as to at least solve the problem in the prior art that the wafer cleaning effect of the single wafer contact cleaning is difficult to meet the production requirements.

In a first aspect, according to an embodiment of the present application, a wafer cleaning method for cleaning a surface of a polished wafer is provided, comprising:
S101, wetting the surface of the wafer with DIW;
S102, spraying the surface of the wafer with SC1 having a first preset temperature;
S103, continuing to spray the surface of the wafer with SC1 having the first preset temperature, and controlling a brush simultaneously to scrub the surface of the wafer;
S104, performing a spray cleaning on the surface of the scrubbed wafer with DIW having a second preset temperature for a first preset time;
S105, repeating the steps S103 to S104 until a first preset number of times;
S106, cleaning the surface of the wafer alternately with DHF and DIO₃ after executing the step S105.

In a second aspect, according to an embodiment of the present application, another wafer cleaning method is provided, comprising:
S201, wetting the surface of the wafer with DIW;
S202, spraying the surface of the wafer with SC1 having a first preset temperature;
S203, continuing to spray the surface of the wafer with SC1 having the first preset temperature, and controlling a brush simultaneously to scrub the surface of the wafer;
S204, performing a mega-sonic cleaning with a preset power on the surface of the wafer after scrubbing;
S205, repeating the steps S203 to S204 until a second preset number of times;
S206, cleaning the surface of the wafer alternately with DHF and DIO₃ after executing the step S205.

In a third aspect, according to an embodiment of the present application, another wafer cleaning method is provided, comprising:
S301, wetting the surface of the wafer with DIW;
S302, spraying the surface of the wafer with SC1 having a first preset temperature;
S303, continuing to spray the surface of the wafer with SC1 having the first preset temperature, and controlling a brush simultaneously to scrub the surface of the wafer and performing a mega-sonic cleaning with a preset power until a second preset time;
S304, cleaning the surface of the wafer alternately with DHF and DIO₃ after executing the step S303.

In a fourth aspect, according to an embodiment of the present application, another wafer cleaning method is provided, comprising:
S401, wetting the surface of the wafer with DIW;
S402, spraying the surface of the wafer with SC1 having a first preset temperature;
S403, continuing to spray the surface of the wafer with SC1 having the first preset temperature, and controlling a brush simultaneously to scrub the surface of the wafer and performing a mega-sonic cleaning with a preset power for a third preset time;
S404, spraying the surface of the wafer with SC1 having the first preset temperature, and controlling the brush to stop scrubbing the surface of the wafer and stopping performing the mega-sonic cleaning with the preset power until a fourth preset time;
S405, repeating the steps S403 to S404 until a third preset number of times;
S406, cleaning the surface of the wafer alternately with DHF and DIO₃ after executing the step S405.

In a fifth aspect, according to an embodiment of the present application, another wafer cleaning method is provided, comprising:
S501, wetting the surface of the wafer with DIW;
S502, spraying the surface of the wafer with SC1 having a first preset temperature;
S503, continuing to spray the surface of the wafer with SC1 having the first preset temperature, and controlling a brush to scrub the surface of the wafer for a fifth preset time;
S504, spraying the surface of the wafer with SC1 having the first preset temperature, and controlling the brush to stop scrubbing the surface of the wafer until a sixth preset time;
S505, repeating the steps S503 to S504 until a fourth preset number of times;
S506, cleaning the surface of the wafer alternately with DHF and DIO₃ after executing the step S505.

According to an embodiment of the present application, a wafer cleaning apparatus is provided, comprising:
a first spraying module, including at least one first spray-head, adapted to spray DIW to the wafer to wet the surface of the wafer and spraying DIW having a second preset temperature to the scrubbed wafer;
a second spraying module, including a second spray-head, for spraying SC1 having a first preset temperature to the wafer;
a first scrubbing module, including a brush, for scrubbing the surface of the wafer;
a first controlling module, connected to the first spraying module, the second spraying module and the first scrubbing module respectively, used to perform the wafer cleaning method according to the first aspect or the fifth aspect.

According to an embodiment of the present application, another wafer cleaning apparatus is provided, comprising:
a third spraying module, including a third spray-head, for spraying DIW to the wafer to wet the surface of the wafer;
a fourth spraying module, including a fourth spray-head, for spraying SC1 having a first preset temperature to the wafer;
a second scrubbing module, including a brush, for scrubbing the surface of the wafer;
a mega-sonic module, including a mega-sonic cleaning apparatus, for performing a mega-sonic cleaning with a preset power;
a second controlling module, connected to the third spraying module, the fourth spraying module, the second scrubbing module and the mega-sonic module respectively, used to perform the wafer cleaning method according to the second, the third or the fourth aspect.

Compared with the prior art, the wafer cleaning method and apparatus for cleaning the surface of the polished wafer provided by the embodiment of the present application adds a transition step of DIW spray cleaning having the second preset temperature or mega-sonic cleaning in multiple and continuous scrubbings, sufficiently removes the residual substances on the surface of the wafer after single scrubbing, effectively improves the cleaning effect of the polished wafer cleaning, and solves the problem of the poor cleaning effect of the wafer in the prior art.

Details of one or more embodiments of the present application are set forth in the following drawings and descriptions, in order to make other features, objects and advantages of the present application more concise and easier to understand.

### BRIEF DESCRIPTION OF THE DRAWINGS

The accompanying drawings described herein are intended to provide a further understanding of the present application, and constitute a part of the present application. The schematic embodiments of the present application and the description are intended to explain the present application, and do not constitute an undue limitation of the present application. In the drawings:

FIG. 1 is a flowchart of a wafer cleaning method according to an embodiment of the present application;

FIG. 2 is a first experimental data diagram of a wafer cleaning method according to an embodiment of the present application;

FIG. 3 is a second experimental data diagram of a wafer cleaning method according to an embodiment of the present application;

FIG. 4 is a third experimental data diagram of a wafer cleaning method according to an embodiment of the present application;

FIG. 5 is a fourth experimental data diagram of a wafer cleaning method according to an embodiment of the present application;

FIG. 6 is a fifth experimental data diagram of a wafer cleaning method according to an embodiment of the present application;

FIG. 7 is a flowchart of a wafer cleaning method according to an embodiment of the present application;

FIG. 8 is a flowchart of a wafer cleaning method according to an embodiment of the present application;

FIG. 9 is a flowchart of a wafer cleaning method according to an embodiment of the present application;

FIG. 10 is a flowchart of a wafer cleaning method according to an embodiment of the present application;

FIG. 11 is a structural block diagram of a wafer cleaning apparatus according to an embodiment of the present application;

FIG. 12 is another structural block diagram of a wafer cleaning apparatus according to an embodiment of the present application.

### PREFERRED EMBODIMENTS OF THE INVENTION

In order to make the objects, technical solutions and advantages of the present application more clearly understood, the present application will be described and illustrated below with reference to the accompanying drawings and embodiments. It is to be understood that the specific embodiments described herein are merely for illustration of the present application and are not intended to limit the present application. Based on the embodiments provided in the present application, all other embodiments obtained by those of ordinary skill in the art under the premise without making creative work belong to the scope of protection of the present application.

Unless otherwise defined, technical terms or scientific terms referred to the present application should have the ordinary meanings as understood by people of ordinary skill in the technical filed of the present application. Similar words such as “a”, “one”, “one kind” and “this” in the present application do not mean a quantitative limitation, and may mean the singular or plural. The terms “comprising”, “including”, “having” and any variations as used in the present application are intended to cover non-exclusive inclusions. For example, a process, method, system, product or apparatus comprising a series of steps or modules (units) is not limited to the listed steps or units, but may further include steps or units not listed, or may further include other steps or units inherent to the process, method, product or apparatus. The terms “connected”, “jointed”, “coupled” and the similar words referred to the present application are not limited to physical or mechanical connections, but may include electrical connections, whether direct or indirect. In the present application, “a plurality” means more than or equal to two. “And/OR” describes the association relationship of the association object, and indicates that there may be three kinds of relationships. For example, “A and/or B” may indicate three cases: A alone, A and B at the same time, and B alone. The terms “first”, “second” and “third” and the like referred to the present application are merely to distinguish similar objects, and do not represent a specific ordering of objects.

After the surface of the wafer is polished by Chemical Mechanical Polishing (CMP), the surface of the wafer is usually cleaned by a single wafer contact cleaning process. The single wafer contact cleaning process is a Radio Corporation of America (RCA) cleaning process. The RCA cleaning method includes: put the wafer in a single brush chamber, wet the surface of the wafer firstly with DIW, then spray the surface of the wafer with SC1 to remove the residual wax on the back surface of the wafer, and then use the brush to scrub the surface of the wafer for successive two times to remove most of the residual polishing solution, finally use DIW to rinse the surface of the wafer to complete the scrubbing process. Then, transfer the wafer to a single cleaning chamber, and clean alternately with DIO₃ and DHF to remove the metal and natural oxide layer on the surface of the wafer, and finally perform DIW spraying and N₂ blow drying. After research, it is found that after the above-mentioned RCA cleaning process is used to complete the cleaning, the LPD (Light Point Defect, indicating raised particles on the surface of the wafer that can be cleaned and removed) particles of and above 0.12 μm on the wafer are 600 ea. The cleaning effect of the above-mentioned RCA cleaning process is limited, and the wafer cleaning effect is poor.

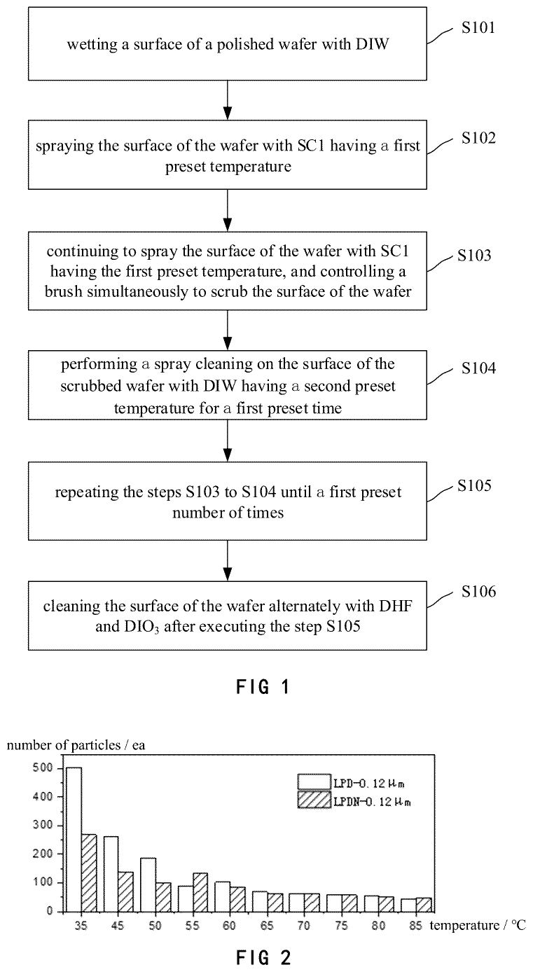

Therefore, in order to solve the problem of the poor wafer cleaning effect described above, an embodiment of the present application provides a wafer cleaning method for cleaning the surface of the polished wafer. FIG. 1 is a flowchart of the wafer cleaning method according to an embodiment of the present application, and as shown in FIG. 1, the method includes the following steps:

step S101, wet the surface of the wafer with DIW.

step S102, spray the surface of the wafer with SC1 having the first preset temperature.

In this step, by spraying SC1 to the surface of the wafer, the particulate impurities and polymers on the wafer can be removed.

Wherein, the SC1 cleaning solution is a mixture of ammonia water, hydrogen peroxide and water, and the volume ratio of the three can be 1:2:50.

step S103, continue to spray the surface of the wafer with SC1 having the first preset temperature, and control a brush simultaneously to scrub the surface of the wafer.

In this step, spray the SC1 having the first preset temperature to the surface of the polished wafer, and control the brush simultaneously to scrub the surface of the wafer. By the method, the dissolution of the organic amine can be further increased, and the purpose of improving the cleaning effect of the wafer can be achieved.

It should be noted that the brush scrubbing is to scrub the front surface and the back surface of the wafer at the same time.

step S104, perform the spray cleaning on the surface of the scrubbed wafer with DIW having the second preset temperature for the first preset time.

It should be noted that the first preset temperature and the second preset temperature may be set according to the wafer cleaning process.

step S105, repeat the steps S103 to S104 until the first preset number of times.

step S106, clean the surface of the wafer alternately with DHF and DIO₃ after executing the step S105.

Based on the above steps S101 to S106, in the present application, by scrubbing the surface of the polished wafer with the brush, then using DIW having the second preset temperature to perform the spray cleaning on the surface of the wafer, and cycling the above operation until the preset number of times, the solubility of the organic amine polishing solution can be increased. Furthermore, the adsorption capacity of particles on the surface of the wafer can be reduced, and the wafer cleaning effect can be improved.

In some embodiments, the temperature of DIW having the second preset temperature may be too high, affecting the properties of the wafer, and causing a portion of LPDN (Light Point Defect Non-cleanable, representing particles that are concave on the surface of the wafer and cannot be cleaned and removed) to easily adsorb on the surface of the wafer. Therefore, in the present embodiment, it is also possible to clean the surface of the wafer after executing the step S105 by using DIW at the normal temperature, so as to avoid the problem that the temperature of the wafer is too high after the DIW spraying at the second preset temperature, and the cleaning effect of the wafer is further improved.

In some embodiments, the cleaning effect of the wafer is affected by factors such as the rotational speed of the wafer, the temperature of the spray cleaning solution, the flow rate of the spray cleaning solution, the duration of the spray cleaning, and the like set in the current application scenario. Therefore, in the present embodiment, in order to further improve the cleaning effect of the wafer, the following methods may be further included:

Method 1, in some embodiments, the second preset temperature may be set between 35° C. and 85° C.

The second preset temperature can be adjusted on the premise that other conditions remain unchanged, as shown in FIG. 2. Based on FIG. 2, it can be concluded that as the temperature increases, the solubility of the organic amine polishing solution can be further increased to a certain extent. In this way, the wafer cleaning effect can be further improved.

It should be noted that In FIG. 2, the ordinate represents the number of particles remaining on the surface of the wafer after the DIW spray cleaning at the second preset temperature. LPD represents Light Point Defect particles, and LPDN represents Light Point Defect Non-cleanable particles. The abscissa represents the temperature corresponding to DIW sprayed at the second preset temperature.

Method 2, in some embodiments, the duration of the DIW spray cleaning at the second preset temperature may be set between 10 seconds and 120 seconds.

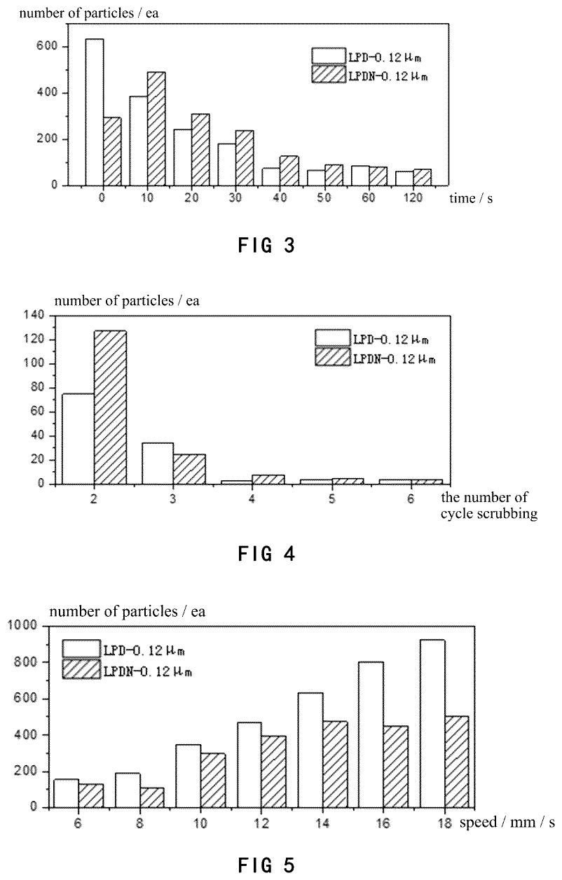

Under the premise that other conditions remain unchanged, the DIW spray cleaning time at the second preset temperature can be adjusted, as shown in FIG. 3. Based on FIG. 3, it can be concluded that the cleaning effect is gradually improved to a certain extent with the increase of the spraying time. And different spraying times can be selected according to different wafer process requirements, so as to achieve the wafer cleaning efficiency and improve the wafer cleaning effect at the same time.

It should be noted in FIG. 3, the ordinate represents the number of particles remaining on the surface of the wafer after the DIW spray cleaning at the second preset temperature. LPD represents Light Point Defect particles, and LPDN represents Light Point Defect Non-cleanable particles. The abscissa represents the spraying time of DIW at the second preset temperature.

Method 3, in some embodiments, the number of cycles in the above steps S103 to S104 can be adjusted on the premise that other conditions remain unchanged. As shown in FIG. 4, as the number of cycles increases, the cleaning effect of the wafer is significantly improved. Therefore, in order to further improve the cleaning effect of the wafer, the first preset number of times in the step S105 can be increased. It should be noted that the preset number of times can be set according to the actual process requirements, so as to meet the requirements of cleaning efficiency and cleaning effect.

It should be noted in FIG. 4, the ordinate represents the number of particles remaining on the surface of the wafer after the DIW spray cleaning at the second preset temperature. LPD represents Light Point Defect particles, and LPDN represents Light Point Defect Non-cleanable particles. The abscissa represents the number of cycle scrubbing.

Method 4, in some embodiments, the scrubbing speed of the brush may also be adjusted between 6 mm/s and 18 mm/s.

Under the premise that other conditions remain unchanged, the scrubbing speed of the brush can be adjusted to further improve the cleaning effect of the wafer. As shown in FIG. 5, as the scrubbing speed of the brush slows down, the cleaning effect of the wafer is gradually improved.

It should be noted in FIG. 5, the ordinate represents the number of particles remaining on the surface of the wafer after the DIW spray cleaning at the second preset temperature. LPD represents Light Point Defect particles, and LPDN represents Light Point Defect Non-cleanable particles. The abscissa represents the scrubbing speed of the brush.

Method 5, in some embodiments, the first preset temperature of SC1 may be adjusted to be 25° C. to 70° C., so as to improve the cleaning effect of the wafer.

Method 6, in some embodiments, the embodiments may also be combined with the above methods 1 to 5, so as to achieve the best cleaning effect.

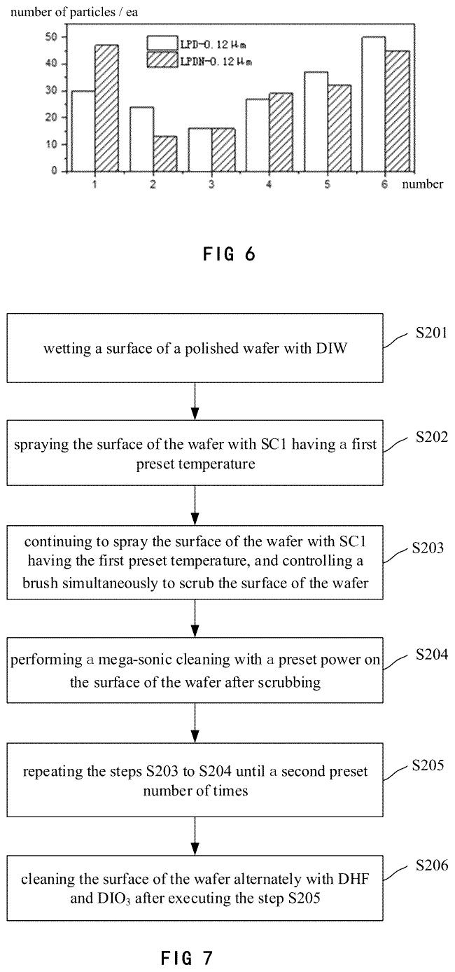

For example, on the premise of fixing the total wafer cleaning time and the first preset number of times in the step S105, the scrubbing speed of the brush and the DIW spraying time of the second preset temperature can be controlled. As shown in Table 1 and FIG. 6 below, it can be seen that when the scrubbing speed of the brush is 10 mm/s, the scrubbing time of the brush and the DIW spraying time at the second preset temperature are close to 1:1, and the cleaning effect is best.

TABLE 1

| Wafer number | 1 | | 2 | | 3 | | 4 | | 5 | | 6 | |
|---|---|---|---|---|---|---|---|---|---|---|---|---|
| Scrubbing speed | 6 | mm/s | 8 | mm/s | 10 | mm/s | 12 | mm/s | 15 | mm/s | 18 | mm/s |
| Single scrubbing time | 27 | s | 23 | s | 20 | s | 17 | s | 15 | s | 12 | s |
| Scrubbing number of times | 3 | | 3 | | 3 | | 3 | | 3 | | 3 | |
| Single DIW spraying time | 10 | s | 15 | s | 20 | s | 25 | s | 28 | s | 32 | s |

| | | | | | | |
|---|---|---|---|---|---|---|
| DIW spraying number of times | 2 | 2 | 2 | 2 | 2 | 2 |

It should be noted that the ordinate in FIG. 6 represents the number of particles remaining on the surface of the wafer after the DIW spray cleaning at the second preset temperature. LPD represents Light Point Defect particles, and LPDN represents Light Point Defect Non-cleanable particles. The abscissa represents the wafer number in Table 1.

In addition to the above-described methods, in some embodiments, the cleaning effect of the wafer can be improved by controlling the flow rate of DIW at the second preset temperature and the rotation speed of the wafer, and the embodiments of the present application will not be exemplified one by one.

In the prior art, in order to ensure the wafer cleaning effect, when the surface of the wafer is alternately cleaned with DHF and DIO₃, the surface of the wafer is alternately cleaned in multiple times. But in the embodiment of the present application, by scrubbing the surface of the polished wafer with the brush, and then performing DIW spray cleaning at the second preset temperature on the surface of the scrubbed wafer, and cycling the above operation to a preset number of times, the solubility of the organic amine polishing solution can be increased. Furthermore, the adsorption capacity of particles on the surface of the wafer can be reduced. And on the premise of ensuring that the improved cleaning effect meets the production demand, the number and time of alternate cleaning of DIF and DIO₃ can be appropriately reduced. And the use of DIF can be reduced, and the possibility of defects in the DHF cleaning process can be reduced, that is, the surface of the wafer can be avoided etching with DHF.

In order to solve the problem of the poor wafer cleaning effect in the prior art, an embodiment of the present application further provides a wafer cleaning method, for cleaning the surface of the polished wafer. FIG. 7 is a flowchart of the wafer cleaning method according to the embodiment of the present application, and as shown in FIG. 7, the method includes the following steps:

S201, wet the surface of the wafer with DIW.

S202, spray the surface of the wafer with SC1 having the first preset temperature.

In this step, by spraying SC1 to the surface of the wafer, the particulate impurities and polymers on the wafer can be removed.

Wherein, the SC1 cleaning solution is a mixture of ammonia water, hydrogen peroxide and water, and the volume ratio of the three can be 1:2:50.

S203, continue to spray the surface of the wafer with SC1 having the first preset temperature, and control the brush simultaneously to scrub the surface of the wafer.

In this step, spray SC1 having the first preset temperature to the polished wafer, and control the brush to scrub the surface of the wafer at the same time, through this method, the dissolution of the organic amine can be further increased, and achieve the purpose of improving the cleaning effect of the wafer.

It should be noted that the brush scrubbing is to scrub the front surface and the back surface of the wafer at the same time.

S204, perform the mega-sonic cleaning with the preset power on the surface of the scrubbed wafer.

In the present embodiment, the cleaning solution of the mega-sonic cleaning is still SC1 at the first preset temperature, and the cleaning of the organic amine can be improved by using the oscillation of the mega-sonic, thereby achieving the purpose of improving the effect and efficiency of the wafer cleaning.

S205, repeat the steps S203 to S204 until the second preset number of times.

S206, clean the surface of the wafer alternately with DHF and DIO₃ after executing the step S205.

Based on the above-described steps S201 to S206, after scrubbing the surface of the polished wafer with the brush, then performing the mega-sonic cleaning with the preset power to the surface of the scrubbed wafer, and circulating the above-described operation for the preset number of times, the residual polishing solution on the surface of the wafer can be removed, and thus improve the wafer cleaning effect

In some embodiments, before the step S206, the surface of the wafer after executing the step S205 may also be cleaned with DIW at the normal temperature.

In this embodiment, the DIW at the normal temperature is adopted to facilitate the reduction of the temperature of the surface of the wafer, so as to avoid the problem that LPDN is easily adsorbed on the surface of the wafer due to the excessively high temperature of the surface of the wafer after the SC1 spraying at the first preset temperature, and further improve the cleaning effect of the wafer.

In some embodiments, the preset power is between 2 W and 10 W. In the present embodiment, the cleaning effect can be gradually improved as the power increases.

In some embodiments, the first preset temperature of SC1 may be adjusted between 25° C. and 70° C., so as to improve the cleaning efficiency of the wafer.

In some embodiments, the second preset number of times in the step S205 is set by the user. In the present embodiment, as the second preset number of times increases, the cleaning effect of the wafer can be improved to a certain extent. Therefore, in order to further improve the cleaning effect of the wafer, the preset number of times in the step S205 can be further increased. It should be noted that the preset number of times can be set according to the actual process requirements, so as to meet the requirements of cleaning efficiency and cleaning effect.

In some embodiments, the scrubbing speed of the brush is between 6 mm/s and 18 mm/s. In this embodiment, under the premise that other conditions remain unchanged, the scrubbing speed of the brush can be adjusted to further improve the cleaning effect of the wafer. And the effect is similar to the effect shown in FIG. 5. As the scrubbing speed of the brush slows down, the cleaning effect of the wafer can be gradually improved, and the detailed description will not be made in this embodiment.

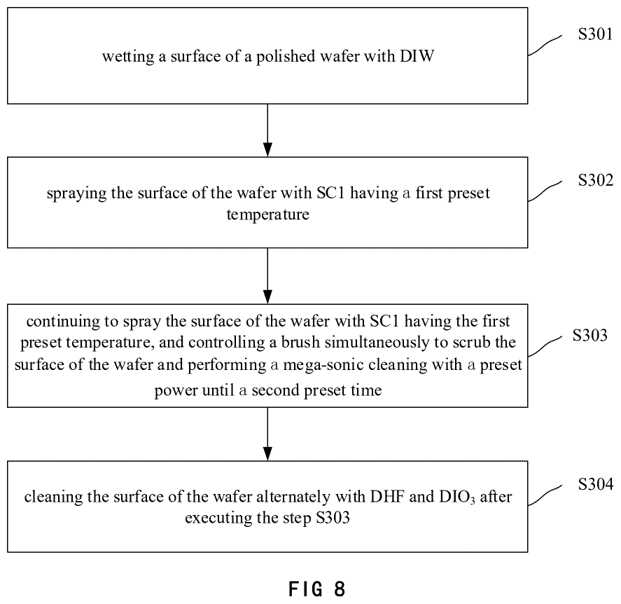

In order to solve the problem of the poor wafer cleaning effect in the prior art, an embodiment of the present application further provides a wafer cleaning method, for cleaning the surface of the polished wafer. FIG. 8 is a flowchart of the wafer cleaning method according to the embodiment of the present application, and as shown in FIG. 8, the method includes the following steps:

S301, wet the surface of the wafer with DIW.

S302, spray the surface of the wafer with SC1 having the first preset temperature.

In this step, by spraying SC1 to the surface of the wafer, the particulate impurities and polymers on the wafer can be removed.

Wherein, the SC1 cleaning solution is a mixture of ammonia water, hydrogen peroxide and water, and the volume ratio of the three can be 1:2:50.

S303, continue to spray the surface of the wafer with SC1 having the first preset temperature, and control the brush simultaneously to scrub the surface of the wafer and perform the mega-sonic cleaning with the preset power, and the time during the brush scrubs the surface of the wafer and performs mega-sonic cleaning with the preset power is the second preset time.

In this step, the SC1 having the first preset temperature is sprayed to the surface of the polished wafer, and the brush is simultaneously controlled to scrub the surface of the wafer and perform the mega-sonic cleaning with the preset power, through the above way, the dissolution of organic amines can be further increased, so that the purpose of improving the wafer cleaning effect can be achieved.

It should be noted that the brush scrubbing is to scrub the front surface and the back surface of the wafer at the same time.

In the present embodiment, the cleaning of organic amines can be improved by using the oscillation of mega-sonic in conjunction with SC1, thereby achieving the purpose of improving the effect and efficiency of wafer cleaning.

S304, clean the surface of the wafer alternately with DHF and DIO₃ after executing the step S303.

Based on the above steps S301 to S304, by spraying SC1 at the first preset temperature to the surface of the wafer, and controlling the brush simultaneously to scrub the surface of the wafer and performing the mega-sonic cleaning with the preset power until the second preset time, the residual polishing solution on the surface of the wafer can be removed, thereby solving the problem of the low wafer cleaning effect of the polished wafer in the prior art and improving the wafer cleaning effect.

In some embodiments, before the step S304, the surface of the wafer after performing the step S303 may be cleaned with DIW at the normal temperature.

In the present embodiment, the DIW at the normal temperature facilitates lowering the temperature of the surface of the wafer, so as to avoid the problem that a part of LPDN is easily adsorbed on the surface of the wafer due to the excessively high temperature of the surface of the wafer after the SC1 spraying at the first preset temperature, and further improve the cleaning effect of the wafer.

In some embodiments, the preset power is between 2 W and 10 W. In the present embodiment, the cleaning effect can be gradually improved as the power increases.

In some embodiments, the first preset temperature of SC1 may be adjusted between 25° C. and 70° C., so as to improve the cleaning efficiency of the wafer.

In some embodiments, the second preset time is set by the user. In the present embodiment, the wafer cleaning effect can be improved by setting the time by the user.

It should be noted that the second preset time can be set according to the actual process requirements, so as to meet the requirements of cleaning effect and cleaning efficiency.

In some embodiments, the scrubbing speed of the brush is between 6 mm/s and 18 mm/s. In this embodiment, under the premise that other conditions remain unchanged, the scrubbing speed of the brush can be adjusted to further improve the cleaning effect of the wafer. And the effect is similar to the effect shown in FIG. 5. As the scrubbing speed of the brush slows down, the cleaning effect of the wafer can be gradually improved, and the detailed description will not be made in this embodiment.

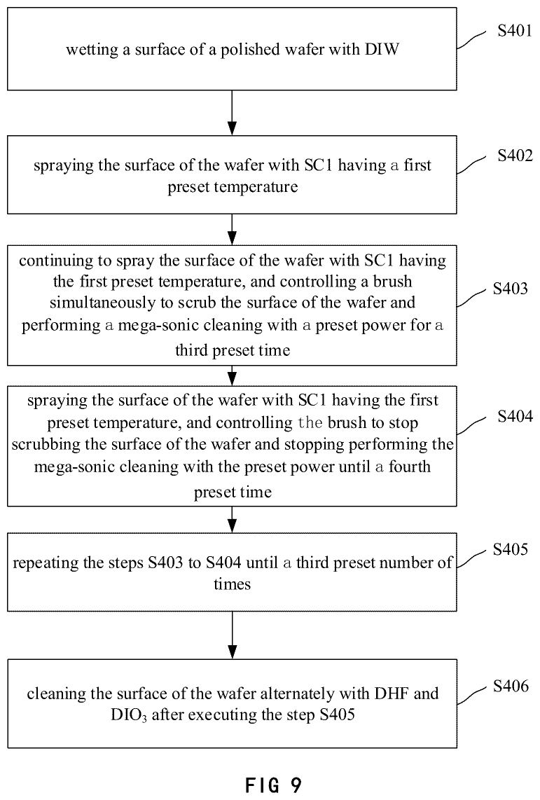

In order to solve the problem of the low wafer cleaning effect in the prior art, an embodiment of the present application further provides a wafer cleaning method, for cleaning the surface of the polished wafer. FIG. 9 is a flowchart of the wafer cleaning method according to the embodiment of the present application, and as shown in FIG. 9, the method includes the following steps:

S401, wet the surface of the wafer with DIW.

S402, spray the surface of the wafer with SC1 having the first preset temperature.

In this step, by spraying SC1 to the surface of the wafer, the particulate impurities and polymers on the wafer can be removed.

S403, continue to spray the surface of the wafer with SC1 having the first preset temperature, and control the brush to scrub the surface of the wafer and perform the mega-sonic cleaning with the preset power for the third preset time.

S404, spray the surface of the wafer with SC1 having the first preset temperature, and control the brush to stop scrubbing the surface of the wafer and stop the mega-sonic cleaning with the preset power until the fourth preset time.

In the above step, the dissolution of organic amines can be further increased, thereby achieving the purpose of improving the wafer cleaning effect.

It should be noted that the brush scrubbing is to scrub the front surface and the back surface of the wafer at the same time.

S405, repeat the steps S403 to S404 until the third preset number of times.

S406, clean the surface of the wafer alternately with DHF and DIO₃ after executing the step S405.

In some embodiments, before the step S406, the surface of the wafer after performing the step S405 may also be cleaned with DIW at the normal temperature.

In the present embodiment, the DIW at the normal temperature facilitates lowering the temperature of the surface of the wafer, so as to avoid the problem that a part of LPDN is easily adsorbed on the surface of the wafer due to the excessively high temperature of the surface of the wafer after the SC1 spraying at the first preset temperature, and further improve the cleaning effect of the wafer.

In some embodiments, the preset power is between 2 W and 10 W. In the present embodiment, the cleaning effect can be gradually improved as the power increases.

In some embodiments, the first preset temperature of SC1 may be adjusted between 25° C. and 70° C., so as to improve the cleaning efficiency of the wafer.

In some embodiments, the third preset time is set by the user. In the present embodiment, the wafer cleaning effect can be improved by setting the time by the user. It should be noted that the third preset time can be set according to the actual process requirements, so as to meet the requirements of cleaning effect and cleaning efficiency.

In some embodiments, the third preset number of times is set by the user. In the present embodiment, as the number of cycles increases, the cleaning effect of the wafer can be improved to a certain extent. Therefore, in order to further improve the cleaning effect of the wafer, the third preset number of times in the step S405 can be further increased. It should be noted that the preset number of times can be set according to the actual process requirements, so as to meet the requirements of cleaning effect and cleaning efficiency.

In some embodiments, the fourth preset time is set by the user. Through this way, the efficiency of wafer cleaning can be improved.

In some embodiments, the scrubbing speed of the brush is between 6 mm/s and 18 mm/s. In the present embodiment, under the premise that other conditions remain unchanged, the scrubbing speed of the brush can be adjusted to further improve the cleaning effect of the wafer, and the effect is similar to the effect shown in FIG. 5. As the scrubbing speed of the brush slows down, the cleaning effect of the wafer can be gradually improved, and the detailed description will not be made in this embodiment.

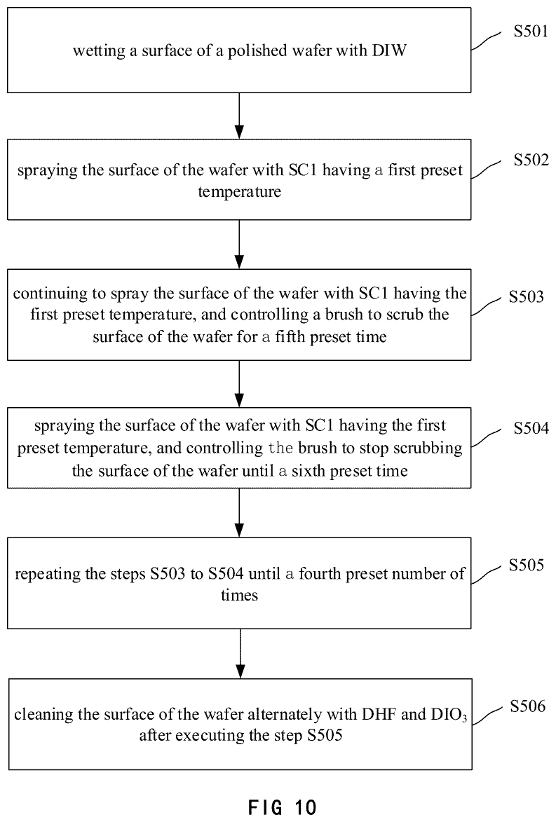

In order to solve the problem of the low wafer cleaning effect in the prior art, an embodiment of the present application further provides a wafer cleaning method, for cleaning the surface of the polished wafer. FIG. 10 is a flowchart of the wafer cleaning method according to the embodiment of the present application, and as shown in FIG. 10, the method includes the following steps:

S501, wet the surface of the wafer with DIW.

S502, spray the surface of the wafer with SC1 having the first preset temperature.

In this step, by spraying SC1 to the surface of the wafer, the particulate impurities and polymers on the wafer can be removed.

Wherein, the SC1 cleaning solution is a mixture of ammonia water, hydrogen peroxide and water, and the volume ratio of the three can be 1:2:50.

S503, continue to spray the surface of the wafer with SC1 having the first preset temperature, and control the brush to scrub the surface of the wafer for the fifth preset time.

S504, spray the surface of the wafer with SC1 having the first preset temperature, and control the brush to stop scrubbing the surface of the wafer until the sixth preset time.

In the above step, through this way, the dissolution of the organic amines can be further increased, thereby achieving the purpose of improving the wafer cleaning effect.

It should be noted that the brush scrubbing is to scrub the front surface and the back surface of the wafer at the same time.

S505, repeat the steps S503 to S504 until the fourth preset number of times.

S506, clean the surface of the wafer alternately with DHF and DIO₃ after executing the step S505.

In some embodiments, before the step S506, the surface of the wafer after performing the step S505 may be cleaned with DIW at the normal temperature.

In the present embodiment, the DIW at the normal temperature facilitates lowering the temperature of the surface of the wafer, so as to avoid the problem that a part of LPDN is easily adsorbed on the surface of the wafer due to the excessively high temperature of the surface of the wafer after SC1 spraying at the first preset temperature, and further improve the cleaning effect of the wafer.

In some embodiments, the first preset temperature of SC1 may be adjusted between 25° C. and 70° C., so as to improve the cleaning efficiency of the wafer.

In some embodiments, the fifth preset time is set by the user. The user can set the time to improve the wafer cleaning effect. It should be noted that the fifth preset time can be set according to the actual process requirements, so as to meet the requirements of cleaning effect and cleaning efficiency.

In some embodiments, the fourth preset number of times is set by the user. In the present embodiment, as the number of cycles increases, the cleaning effect of the wafer can be improved to a certain extent. Therefore, in order to further improve the cleaning effect of the wafer, the fourth preset number of times in the step S505 can be further increased. It should be noted that the preset number of times can be set according to the actual process requirements, so as to meet the requirements of cleaning effect and cleaning efficiency.

In some embodiments, the sixth preset time is set by the user. The user can set the time to improve the wafer cleaning effect. It should be noted that the sixth preset time can be set according to the actual process requirements, so as to meet the requirements of cleaning effect and cleaning efficiency.

In some embodiments, the scrubbing speed of the brush is between 6 mm/s and 18 mm/s. In the present embodiment, under the premise that other conditions remain unchanged, the scrubbing speed of the brush can be adjusted to further improve the cleaning effect of the wafer. And the effect is similar to the effect shown in FIG. 5, and the cleaning effect of the wafer can be gradually improved as the scrubbing speed of the brush decreases, and the detailed description will not be made in this embodiment.

After the wafer cleaning is completed, the surface of the wafer may be dried with the drying gas, such as helium, nitrogen, or the like.

Based on the above embodiment, in the embodiment of the present application, by adding the transition step in the continuous scrubbing of multiple times, the residual substances on the surface of the wafer after single scrubbing are sufficiently removed, and the cleaning effect of the single wafer contact cleaning process on the polished wafer can be effectively improved.

The present application also provides a wafer cleaning apparatus, for cleaning the surface of the polished wafer, and the apparatus is used to realize the above embodiments, and the above-mentioned description will not be repeated. The terms “module”, “unit”, “sub-unit” and the like, as used below, may be combinations of software and/or hardware that implement predetermined functions.

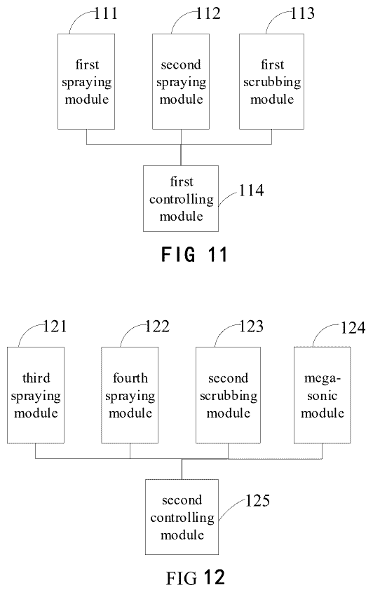

FIG. 11 is a structural block diagram of a wafer cleaning apparatus for cleaning the surface of the polished wafer according to the embodiment of the present application, and as shown in FIG. 11, the apparatus comprising:
a first spraying module 111, including at least one first spray-head, adapted to spray DIW to the surface of the wafer to wet the surface of the wafer and spraying DIW having the second preset temperature to the scrubbed wafer;
a second spraying module 112, including a second spray-head, for spraying SC1 having the first preset temperature to the surface of the wafer;
a first scrubbing module 113, including a brush, for scrubbing the surface of the wafer;
a first controlling module 114, connected to the first spraying module 111, the second spraying module 112 and the first scrubbing module 113 respectively, used to execute the wafer cleaning method of spraying with DIW at the second preset temperature as described above.

It should be noted that one first spray-head may be provided to spray DIW to the surface of the wafer to wet the surface of the wafer, and the DIW having the second preset temperature may be sprayed to the scrubbed wafer, or two first spray-heads may be provided to realize the two functions respectively. It should be understood when required, as described above, at least one first spray-head to be capable of spraying DIW having the second preset temperature to the scrubbed wafer, whether by a single spray-head or an additional spray-head. However, when it is not necessary to spray DIW having the second preset temperature, the sections for performing the present operation are not configured, for example, only providing a single spray-head.

In some embodiments thereof, the first preset temperature may be between 25° C. and 70° C.

In some embodiments thereof, the second preset temperature may be between 35° C. and 85° C.

In some embodiments thereof, the duration of the DIW spray cleaning at the second preset temperature may be between 10 seconds and 120 seconds.

In some embodiments thereof, the scrubbing speed of the brush may be set between 6 mm/s and 18 mm/s.

FIG. 12 is another structural block diagram of a wafer cleaning apparatus for cleaning the surface of the polished wafer according to the embodiment of the present application, and as shown in FIG. 12, the apparatus comprising:
a third spraying module 121, including a third spray-head, for spraying DIW to the surface of the wafer to wet the surface of the wafer;
a fourth spraying module 122, including a fourth spray-head, for spraying SC1 having the first preset temperature to the surface of the wafer;
a second scrubbing module 123, including a brush, for scrubbing the surface of the wafer;
a mega-sonic module 124, including a mega-sonic cleaning apparatus, for performing the mega-sonic cleaning with the preset power;
a second controlling module 125, connected to the third spraying module 121, the fourth spraying module 122, the second scrubbing module 123 and the mega-sonic module 124 respectively, for performing the wafer cleaning method using mega-sonic cleaning as described above.

In some embodiments thereof, the first preset temperature may be between 25° C. and 70° C.

In some embodiments thereof, the scrubbing speed of the brush may be set between 6 mm/s and 18 mm/s.

In some embodiments thereof, the preset power may be between 2 W and 10 W.

People skilled in the art should understand that the technical features of the above-described embodiments can be combined arbitrarily. In order to make the description concise, all possible combinations of the technical features of the above-described embodiments have not been described. However, as long as there is no contradiction between the combinations of these technical features, the technical features should be considered to be within the scope of the present specification.

The above-described embodiments only express some embodiments of the present application, and the description is relatively specific and detailed, but should not be understood as limiting the scope of the patent invention. It should be pointed out that for those of ordinary skill in the art, several modifications and improvements can be made without departing from the concept of the present application, and the modifications and improvements are all within the scope of protection of the present application. Therefore, the scope of protection of this patent application should be subject to the appended claims.

1. A wafer cleaning method, for cleaning a surface of a polished wafer, comprising:
S101, wetting the surface of the wafer with DIW;
S102, spraying the surface of the wafer with SC1 having a first preset temperature;
S103, continuing to spray the surface of the wafer with SC1 having the first preset temperature, and controlling a brush simultaneously to scrub the surface of the wafer;
S104, performing a spray cleaning on the surface of the scrubbed wafer with DIW having a second preset temperature for a first preset time;
S105, repeating the steps S103 to S104 until a first preset number of times;
S106, cleaning the surface of the wafer alternately with DHF and DIO₃ after executing the step S105.

2. The wafer cleaning method according to claim 1, before the step S106, the method further comprising:
cleaning the surface of the wafer with DIW at a normal temperature after executing the step S105.

3. The wafer cleaning method according to claim 1, wherein the first preset temperature is between 25° C. and 70° C.

4. The wafer cleaning method according to claim 1, wherein the first preset time is between 10 s and 120 s.

5. The wafer cleaning method according to claim 1, wherein the second preset temperature is between 35° C. and 85° C.

6. The wafer cleaning method according to claim 1, wherein a scrubbing speed of the brush is between 6 mm/s and 18 mm/s.

7.-21. (canceled)

22. A wafer cleaning method, for cleaning a surface of a polished wafer, comprising:
S501, wetting the surface of the wafer with DIW;
S502, spraying the surface of the wafer with SC1 having a first preset temperature;
S503, continuing to spray the surface of the wafer with SC1 having the first preset temperature, and controlling a brush to scrub the surface of the wafer for a fifth preset time;
S504, spraying the surface of the wafer with SC1 having the first preset temperature, and controlling the brush to stop scrubbing the surface of the wafer until a sixth preset time;
S505, repeating the steps S503 to S504 until a fourth preset number of times;
S506, cleaning the surface of the wafer alternately with DHF and DIO₃ after executing the step S505.

23. The wafer cleaning method according to claim 22, before step S506, the method further comprising:
cleaning the surface of the wafer with DIW at a normal temperature after executing the step S505.

24. The wafer cleaning method according to claim 22, wherein the first preset temperature is between 25° C. and 70° C.

25. The wafer cleaning method according to claim 22, wherein a scrubbing speed of the brush is between 6 mm/s and 18 mm/s.

26. A wafer cleaning apparatus, for cleaning a surface of a polished wafer, comprising:
a first spraying module, including at least one first spray-head, adapted to spray DIW to the surface of the wafer to wet the surface of the wafer and spray DIW having a second preset temperature to the surface of the scrubbed wafer;
a second spraying module, including a second spray-head, for spraying SC1 having a first preset temperature to the surface of the wafer;
a first scrubbing module, including a brush, for scrubbing the surface of the wafer;
a first controlling module, connected to the first spraying module, the second spraying module and the first scrubbing module respectively, for executing the wafer cleaning method according to claim 1.

27. The wafer cleaning apparatus according to claim 26, wherein the first preset temperature is between 25° C. and 70° C.

28. The wafer cleaning apparatus according to claim 26, wherein the second preset temperature is between 35° C. and 85° C.

29. The wafer cleaning apparatus according to claim 26, wherein a cleaning time of spraying the DIW at the second preset temperature is between 10 s and 120 s.

30. The wafer cleaning apparatus according to claim 26, wherein a scrubbing speed of the brush is set between 6 mm/s and 18 mm/s.

31.-34. (canceled)

35. A wafer cleaning apparatus, for cleaning a surface of a polished wafer, comprising:
a first spraying module, including at least one first spray-head, adapted to spray DIW to the surface of the wafer to wet the surface of the wafer and spray DIW having a second preset temperature to the surface of the scrubbed wafer;
a second spraying module, including a second spray-head, for spraying SC1 having a first preset temperature to the surface of the wafer;
a first scrubbing module, including a brush, for scrubbing the surface of the wafer;
a first controlling module, connected to the first spraying module, the second spraying module and the first scrubbing module respectively, for executing the wafer cleaning method according to claim 22.

36. The wafer cleaning apparatus according to claim 35, wherein the first preset temperature is between 25° C. and 70° C.

37. The wafer cleaning apparatus according to claim 35, wherein the second preset temperature is between 35° C. and 85° C.

38. The wafer cleaning apparatus according to claim 35, wherein a cleaning time of spraying the DIW at the second preset temperature is between 10 s and 120 s.

39. The wafer cleaning apparatus according to claim 35, wherein a scrubbing speed of the brush is set between 6 mm/s and 18 mm/s.
